(19) United States
(12) Patent Application Publication
(10) Pub. No.: US 2025/0148181 A1
(43) Pub. Date: May 8, 2025

(54) SIGNAL PROPAGATION SIMULATION INCLUDING PHOTONIC DEVICE-TO-PHOTONIC DEVICE CONNECTIVITY AWARENESS

(71) Applicant: GlobalFoundries U.S. Inc., Malta, NY (US)

(72) Inventors: Bradley A. Orner, Ben Lomond, CA (US); Romain H.A. Feuillette, Williston, VT (US); Vivienne A.B. Miller, Ellicott City, MD (US); Petar Ivanov Todorov, Sofia (BG); Stephen T. Burgess, Sofia (BG)

(21) Appl. No.: 18/503,212

(22) Filed: Nov. 7, 2023

(51) Int. Cl. G06F 30/3308; G02B 27/00

(52) U.S. Cl. CPC G06F 30/3308; G02B 27/0012

(57) ABSTRACT

Disclosed are a photonic integrated circuit (PIC) design system and method including optical signal propagation simulation with coupling awareness to account for transition loss due to a difference between at least one specific physical parameter (e.g., curvature radius, material composition, etc.) in optically coupled photonic devices. Coupling awareness can be achieved by including, within a bus of a netlist between the photonic devices, at least one pair of physical data pins: one associated with a specific physical parameter in the light emitting photonic device and the other associated with the specific physical parameter in the light receiving photonic device. Alternatively, coupling awareness can be achieved by running a utility to identify a parameter mismatch between the light emitting and receiving photonic devices, developing a custom coupling cell to account for the mismatch, and inserting the custom coupling cell into a design layout for the PIC.

### BACKGROUND

The present disclosure relates to photonic integrated circuit (PIC) design and, more particularly, to systems and methods that include an optical signal propagation simulation tool for use in PIC design.

During conventional integrated circuit (IC) design, netlists are extracted from a design and electrical simulations of the IC are performed (e.g., by a conventional simulation tool, such as a simulation program with integrated circuit emphasis (SPICE) tool) using the extracted netlists. If the performance models indicate that the chips will perform as required by the design specifications, the design layout will be verified and can be released for manufacturing. If not, the design layout will not be verified, and further iterative chip design processing will be required. With advances in technology, integrated circuit (IC) designs often incorporate photonic devices. Such photonic devices can include, but are not limited to, waveguides, laser diodes, light-emitting diodes, optical couplers, optical splitters, optical amplifiers, photodetectors (also referred to herein as photosensors), bends, polarization beam splitter and rotators (PSRs), optical modulators, and optical filters. ICs that include photonic devices are referred to as PICs. To accurately model PIC performance, simulations must account for electric and optical signals. Recently, simulation tools have been developed for use in PIC design and, particularly, for simulating optical signal propagation therein. However, such simulation tools currently have limited functionality.

### SUMMARY

Disclosed herein are embodiments of a system for designing a photonic integrated circuit (PIC). The system can include a storage medium, which stores a netlist for the PIC under design. The system can further include a processor, which is in communication with the storage medium. The processor can access netlist from the storage medium and can perform a signal propagation simulation using the netlist. This signal propagation simulation can, for example, account for signal loss due to a difference between a specific physical parameter of a first photonic device and the same specific physical parameter of a second photonic device that receives an optical signal from the first photonic device.

Also disclosed herein are embodiments of a method for designing a PIC. The method can include accessing, by a processor from a storage medium, a netlist for the PIC. The method can further include performing, by the processor, a signal propagation simulation using the netlist. The signal propagation simulation can, for example, account for signal loss due to a difference in a specific physical parameter of a first photonic device and the same specific physical parameter of a second photonic device that receives an optical signal from the first photonic device.

Also disclosed herein are embodiments of a product (e.g., a process design kit (PDK)) that includes a computer readable storage medium with program instructions embodied therewith. The program instructions are executable by a processor to cause the processor to perform the above-described method.

It should be noted that all aspects, examples, and features of disclosed embodiments mentioned in the summary above can be combined in any technically possible way. That is, two or more aspects of any of the disclosed embodiments, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWINGS

The present disclosure will be better understood from the following detailed description with reference to the drawings, which are not necessarily drawn to scale and in which:

FIGS. 1A-1D are layout diagrams illustrating examples of different physical parameter mismatches that can occur between optically coupled photonic devices within a PIC design;

FIG. 2 is a flow diagram illustrating disclosed embodiments of a PIC design method;

FIG. 3 is a schematic diagram illustrating disclosed embodiments of a computer-aided design (CAD) system;

FIG. 4A is a drawing illustrating a portion of a PIC design layout including three optically coupled photonic devices;

FIGS. 4B-4C include lists of defined optical signal and physical data input and output pins for the photonic devices in FIG. 4A;

FIG. 5A is a drawing illustrating a portion of an initial PIC design layout including three optically coupled photonic devices;

FIGS. 5B-5C include lists of defined optical signal input and output pins for the photonic devices in FIG. 5A;

FIG. 5D is a drawing illustrating a portion of an updated PIC design layout generated following running of a mismatch utility and including custom-coupling cells inserted between the three optically coupled photonic devices of FIG. 5A to provide physical parameter mismatch information; and

FIG. 6 is a schematic diagram illustrating an example hardware environment for implementing aspects of the disclosed systems, methods and computer program products.

### DETAILED DESCRIPTION

For purposes of this disclosure, “optically coupled photonic devices” are photonic devices that may be physically separated (e.g., by cladding material) but sufficiently close so that optical signals can pass between them and, particularly, so that optical signals can pass between adjacent end portions along a location where mode matching occurs (i.e., where the propagation constant of optical mode inside the two waveguides becomes the same). When optical signals are propagated from one photonic device to another, optical signal loss occurs in each of the photonic devices. Recently, simulation tools have been developed for use in PIC design and, particularly, for simulating optical signal propagation therein. However, such simulation tools have limited functionality. For example, currently available simulation tools typically calculate total optical signal loss during optical signal propagation between two optically coupled photonic devices as being equal to the sum of the losses from each of the photonic devices. However, if there are one or more physical parameter mismatches between the two optically coupled photonic devices, additional optical signal transition loss may occur. These losses are not accounted for in the total optical signal loss calculation. Such optical signal transition loss can occur, for example, when there is a mismatch in curvature radius (i.e., when the curvature radius of a first photonic device is different from that of a second photonic device optically coupled thereto), a mismatch in material composition (i.e., when the material or stack of materials of a first photonic device is different from the material or stack of materials of a second photonic device optically coupled thereto), a mismatch in a physical dimension, such as width or cross-sectional area (e.g., when a particular physical dimension of a first photonic device is different from the particular physical dimension of a second photonic device optically coupled thereto), etc.

In view of the foregoing, disclosed herein are embodiments of a system and method for designing PICs. The embodiments employ optical signal propagation simulation with improved functionality including photonic device-to-photonic device connectivity awareness (i.e., optical coupling awareness). Specifically, to ensure that a PIC will perform as intended, such optical signal propagation simulation can, among other things, account for optical signal transition loss between optically coupled photonic devices having a physical parameter mismatch. That is, it can account for optical signal transition loss due to a difference between at least one specific physical parameter (e.g., curvature radius, material composition, a physical dimension, etc.) of optically coupled photonic devices. In some embodiments, such coupling awareness can be achieved by including, within a virtual bus in a netlist between optically coupled photonic devices, at least one pair of physical data pins. The pair of physical data pins can include one pin associated with a specific physical parameter of a first photonic device, which emits an optical signal (also referred to herein as a light signal), and a corresponding pin associated with the specific physical parameter in a second photonic device, which receives the optical signal. The simulation is performed using the netlist including parameter mismatch information communicated via the pins. In other embodiments, such coupling awareness can be achieved by running a utility to identify a mismatch in the physical parameter between the optically coupled photonic devices, developing a custom coupling cell that defines the physical parameter mismatch, and inserting the custom coupling cell into a design layout for the PIC. The simulation is performed using an updated netlist including parameter mismatch information communicated via the custom coupling cell. It should be noted that the tools needed to perform the method can be embodied on a computer readable storage medium of a computer program product or, alternatively, of a process design kit (PDK) product.

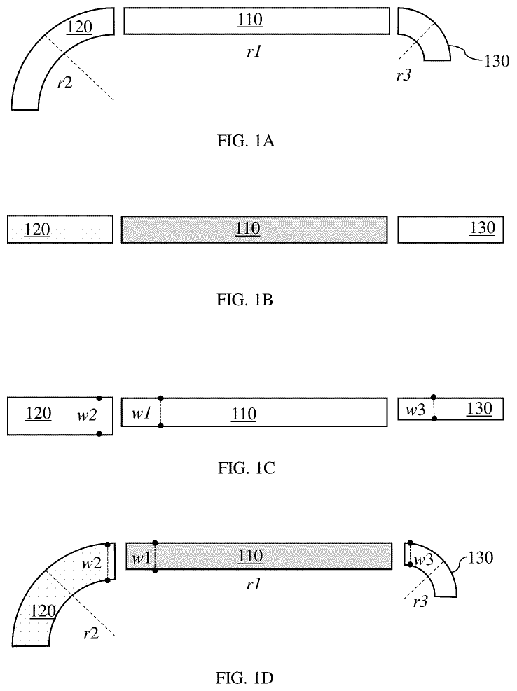

Examples of physical parameter mismatches between optically coupled photonic devices are shown in FIGS. 1A-1D. FIG. 1A illustrates a first photonic device 110 having a different curvature radius than a second photonic device 120 from which an optical signal is received and a third photonic device 130 to which an optical signal is emitted. FIG. 1B illustrates a first photonic device 110 made of a different material composition (e.g., a different material or stack of materials) than a second photonic device 120 from which an optical signal is received and a third photonic device 130 to which an optical signal is emitted. FIG. 1C illustrates a first photonic device 110 having a different dimension (e.g., a different width, a different cross-sectional area, etc.) than a second photonic device 120 from which an optical signal is received and a third photonic device 130 to which an optical signal is emitted. FIG. 1D illustrates a first photonic device 110 having a different curvature radius, a different material composition, and a different dimension than a second photonic device 120 from which an optical signal is received and a third photonic device 130 to which an optical signal is emitted. Currently available optical signal propagation simulation techniques generally are known to produce accurate results when there are no physical parameter mismatches (e.g., when the curvature radius of optically coupled photonic devices is the same, when the material composition of optically coupled photonic devices is the same, when the cross-sectional area of optically coupled devices is the same, etc.). However, they do not account for optical signal transition loss when there are physical parameter mismatches (e.g., as shown in FIG. 1A-1D). These examples of parameter mismatch are provided for illustration purposes and are not intended to be limiting. It should be understood that other types of parameter mismatch between optically coupled photonic devices or combinations thereof could result in optical signal transition loss.

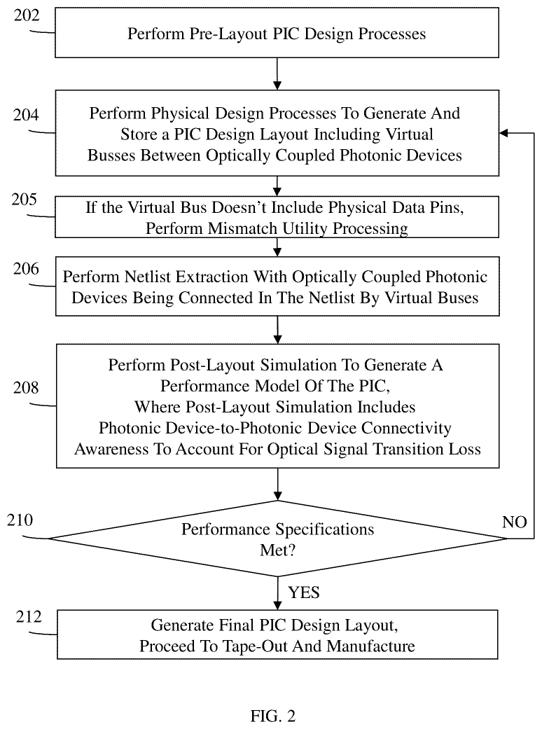

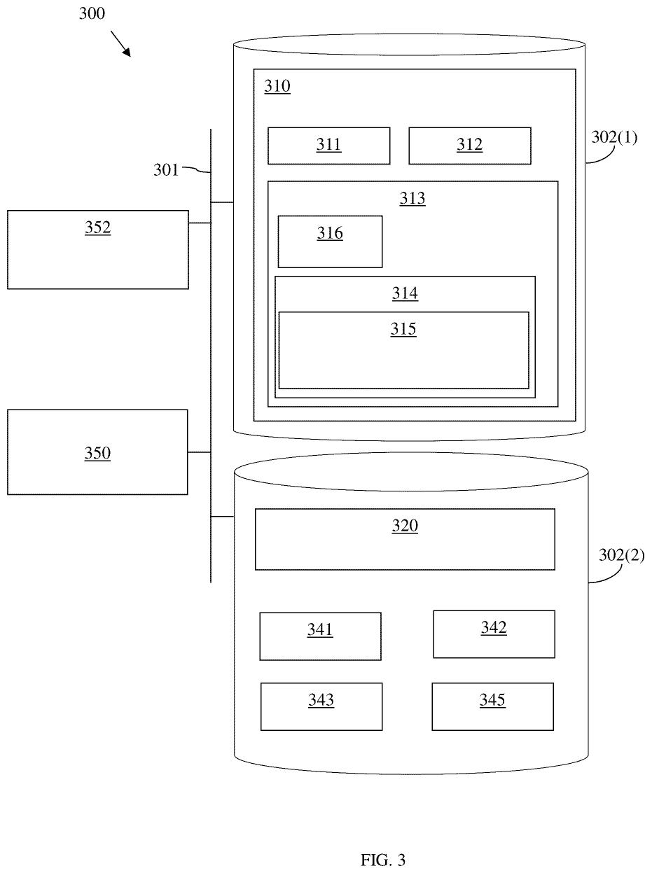

FIG. 2 is a flow diagram illustrating disclosed embodiments of a PIC design method that includes optical signal propagation simulation that models, and thus accounts for, optical signal transition loss due to physical parameter mismatches between optically coupled photonic devices (e.g., as shown in FIGS. 1A-1D). FIG. 3 is a schematic diagram illustrating disclosed embodiments of a computer-aided design (CAD) system 300, which can be employed to implement the disclosed PIC design method, and which is configured to perform optical signal propagation simulation that models and, thus, accounts for optical signal transition loss due to physical parameter mismatches between optically coupled photonic devices.

Referring to FIGS. 2 and 3 in combination, the disclosed method and system embodiments can be implemented using, for example, a process design kit (PDK) 310, which can be stored on a PDK product (e.g., a non-transitory computer readable storage medium) or other storage medium. Those skilled in the art will recognize that a PDK 310 refers to a kit developed by a semiconductor foundry to facilitate design at a technology node supported by the foundry. For example, PDK 310 could be developed for a 300 mm silicon platform, which allows for integration of both silicon photonic (SiPh) devices and radio frequency (RF) complementary metal oxide semiconductor (CMOS) devices in the same PIC chip. Alternatively, PDK 310 could be developed for any other platform suitable for PIC design.

PDK 310 can include electronic files for various design components. The components can include, but are not limited to, a library 311 of cells (also referred to herein as a cell library). The cells in library 311 can include standard cells and/or parameterized cells (Pcells) for electronic devices and for photonic devices (including optoelectronic devices), which are selectable for inclusion in a PIC design. For purposes of this disclosure, a “standard cell” represents a circuit component (including one or more devices and the electrical and/or optical connections therebetween) with a fixed set of parameters, while a “parameterized cell” (also referred to in the art as a template cell) similarly represents a circuit component (including one or more devices and the electrical and/or optical connections therebetween) but with customizable parameters. Such cells are known in the art and, thus, the details thereof have been omitted from the specification in order to allow the readers to focus on the salient aspects of the disclosed embodiments. Additionally, for purposes of this disclosure, photonic devices (including optoelectronic devices) refer to devices configured to create, manipulate, process, propagate, or detect light signals (i.e., optical signals). Such photonic devices can include, but are not limited to, waveguides, laser diodes, light-emitting diodes, optical couplers, optical splitters, optical amplifiers, photodetectors (also referred to herein as photosensors), bends, polarization splitter-rotators (PSRs), optical modulators, and optical filters. Such photonic devices are well known in the art and, thus, the details thereof have been omitted from this specification in order to allow the reader to focus on the salient aspects of the disclosed embodiments. In any case, each cell in the cell library 311 can include a component description (e.g., in a component description format (CDF)) that defines the parameters and attributes of the device represented by that particular cell.

PDK 310 can further include various design data files 312. Design data files 312 can include, but are not limited to, symbols and technology files for the specific technology node, design rule decks for various stages in the design process, etc. PDK 310 can also include program files including one or more electronic design automation (EDA) tools 313. For example, EDA tools 313 can include one or more simulation programs 314. As discussed in greater detail below, at least one of the simulation programs 314 can be an optical signal propagation simulation program 315 (also referred to herein as an optical simulation tool). The optical signal propagation program 315 can include program instructions that are executable by a processor for forward optical signal propagation simulation and, optionally, for performing bidirectional optical signal propagation simulation (i.e., for both forward and reverse optical signal propagation simulation). These program instructions can further be written to account for transition loss due to physical parameter mismatches during forward and/or reverse optical signal propagation. Optionally, the EDA tools 313 can further include a mismatch utility 316 (discussed in greater detail below).

In practice, a PDK product can be made accessible to foundry customers and, particularly, to CAD system(s) 300 thereof. Specifically, a CAD system 300 can include one or more processors 350, one or more user interface devices 352 (e.g., monitors, displays, etc.), and one or more computer-readable storage mediums or devices (e.g., see storage mediums 302(1)-302(2)), which are accessible by the processor(s) 350. The various components of CAD system 300 can include, but are not limited to, the processor(s) 350, user interface device(s) 352, and storage mediums(s) 302(1)-302(2) interconnected either over a system bus 301, as illustrated, and/or over a wired or wireless network (not shown). The various components of CAD system 300 can be co-located. Alternatively, CAD system 300 can be a client-server system with a central server and multiple networked workstations. Alternatively, CAD system 300 can be a distributed system whose components are distributed across different networked computers. In any case, for purposes of illustration, CAD system 300 is illustrated in FIG. 3 as if it incorporates only a single processor 350, a single user interface device 352, and two storage mediums 302(1)-302(2). However, it should be understood that, alternatively, CAD system 300 can incorporate multiple processors 350 for performing one or more of the different steps in the design flow, as discussed below, multiple user interface devices 352, and any number of one or more storage mediums, which store the data and programs (i.e., software tools or applications) that are employed during the different steps in the design flow.

Storage medium 302(1) can store PDK 310. As mentioned above, the PDK product can be in the form of a computer-readable storage medium having PDK 310 embodied therewith (e.g., stored thereon). Storage medium 302(1) can be the PDK product itself (e.g., a disk, flash drive, portable hard drive, etc.), which is accessible by a processor 350 of CAD system 300 through an interface (e.g., via a disk reader, USB port, or other interface, as appropriate). Alternatively, PDK 310 can be loaded onto storage medium 302(1) from the PDK product.

Storage medium 302(2) can store additional EDA tools 320 (i.e., EDA software programs or applications) not otherwise provided by PDK 310. Examples of such additional EDA tools 320 can include, but are not limited to, a partitioning tool, a floorplanning tool, a placement tool, a signal routing tool, a netlist extraction tool, a layout versus schematic tool, a design rule checking tool, one or more simulation tool(s), and optionally other utilities. Based on user inputs (e.g., received via a user interface device 352) and based on information contained in PDK 310, the processor(s) 350 can execute EDA tools 313 and/or 320 at different stages in the development of a PIC design and can store the results from each stage (e.g., in the storage medium 302(2)).

Generally, the disclosed method embodiments (as shown in FIG. 2) can be implemented using the disclosed system embodiments and, particularly, using the CAD system 300, including the PDK 310 and EDA tools 313, 320 (as shown in FIG. 3), as described below.

For example, the embodiments can include performing pre-layout design processes for a PIC (see process 202). The pre-layout design processes can be performed by processor 350 (executing one or more of the EDA tools 313, 320) based on inputs received from a user via a user interface device 352. Such pre-layout design processes are well known in the art and, thus, the details thereof have been omitted from the specification to allow the reader to focus on the salient aspects of the disclosed embodiments. However, generally, such pre-layout design processes include, but are not limited to, developing an initial design for the PIC based on design and performance specification inputs and, particularly, developing a description of the PIC coded in, for example, a SPICE netlist, Verilog-A, or any other suitable means of expressing the design elements and their connectivity within the PIC.

Physical design processes can be performed to transform the PIC description into a physical layout and, particularly, to generate a design layout 341 for the PIC that describes the position of cells and interconnections therebetween (see process 204). The physical design processes can be performed by processor 350 (executing one or more of the EDA tools 313, 320) based on inputs received from a user via a user interface device 352. Such physical design processes are well known in the art and, thus, the details thereof have been omitted from the specification in order to allow the reader to focus on the salient aspects of the disclosed embodiments. However, the physical design processes can include, but are not limited to the following: floorplanning, placement, optical and electrical connections, signal loss budgeting, and phase matching. Those skilled in the art will further recognize that physical design processes are performed based on design rules. The design rules can be included in rule decks (e.g., provided in the PDK) for one or more of the particular processes in the design flow. In any case, the design layout 341 developed at process 204 can be stored in a storage medium (e.g., storage medium 302(2) accessible by the processor 350).

Following the physical design processes, netlist extraction can be performed and the resulting post-layout netlist 342 can be stored (see process 206). That is, the design layout 341 can be translated back into a netlist to facilitate performing various other post-layout processes including, but not limited to, a layout versus schematic (LVS) and post-layout simulation (see discussion of post-layout simulation below). It should be noted that optically coupled photonic devices can be depicted in the post-layout netlist 342 as being connected by a virtual bus. The post-layout netlist 342 can be extracted and stored at process 206 by processor 350 (executing a netlist extraction tool).

Post-layout simulation(s) can be performed using the post-layout netlist 342, the resulting simulation results 345 can be stored, and further output to a user (see process 208). Post-layout simulation(s) can be performed by the processor 350 executing one or more the simulation tools of the EDA tools 313, 320 and the simulation results 345 can be stored in storage medium 302(2) and further output to a user (either automatically or on-demand, as discussed further below). The simulation tool(s) executed by the processor 350 can at least include the optical signal propagation simulation program 315, which is configured for forward optical signal propagation simulation and, optionally, for bidirectional optical signal propagation simulation. For purposes of this disclosure, bidirectional optical signal propagation refers to both forward propagation of an optical signal and reverse propagation (also referred to herein as reflected propagation) of the same optical signal. In any case, in the disclosed embodiments, the optical signal propagation simulation program 315 can be configured to perform such optical signal propagation simulation with connectivity awareness (i.e., optical coupling awareness) to account for optical signal transition loss due to physical parameter mismatches between any two optically coupled photonic devices in the PIC design layout, as discussed below.

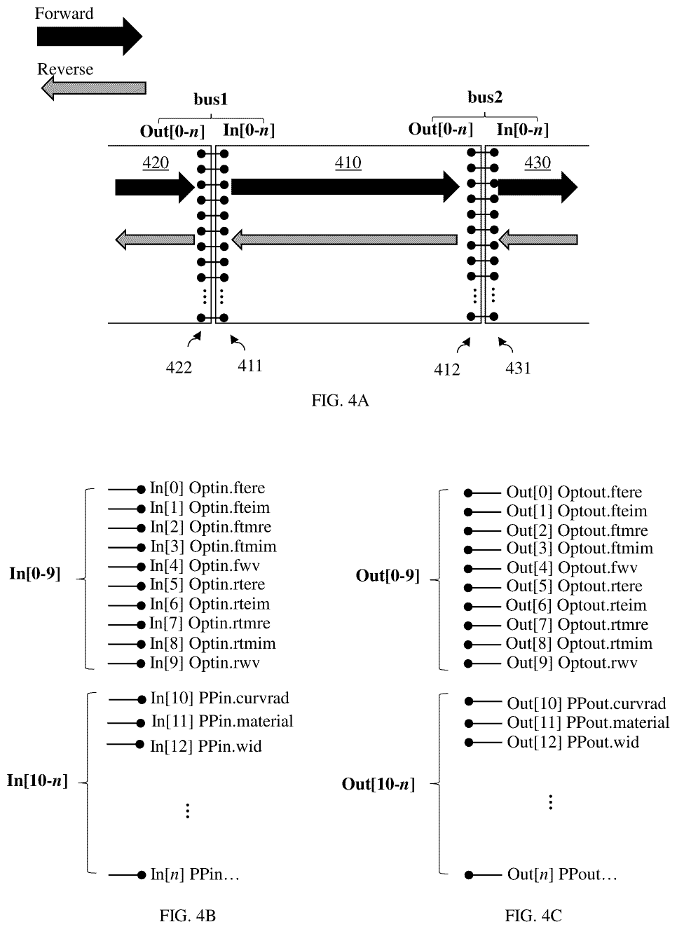

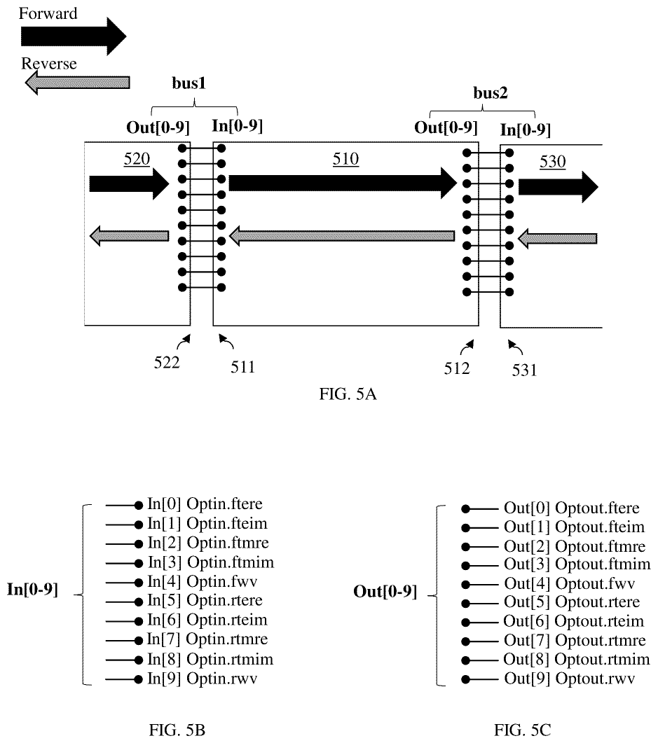

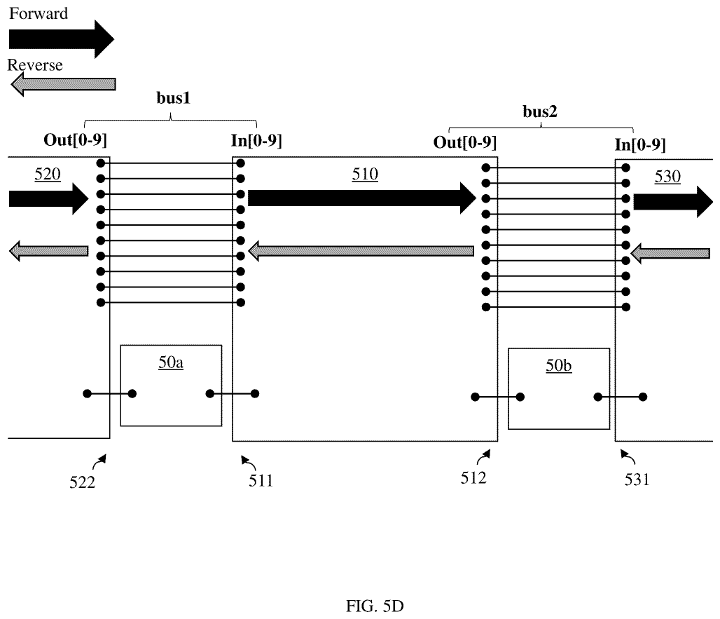

FIGS. 4A-4C and FIGS. 5A-5D illustrate different techniques, respectively, that can be employed by the optical signal propagation simulation program 315 to achieve coupling awareness during simulation at process 208 of FIG. 2 to account for optical signal transition loss.

Referring to FIGS. 4A-4C, in some embodiments, this coupling awareness can be achieved through the use of physical data pins, which define physical parameter information and which are included in a virtual bus between optically coupled photonic devices in a design layout. Specifically, component descriptions (in CDF) of the photonic device cells in the cell library 311 can include optical signal input pins at each input terminal (i.e., at each light receiving terminal) of a photonic device cell and optical signal output pins at each output terminal (i.e., at each light emitting terminal) of a photonic device cell. These optical signal input and output pins can be defined to account for different components of light signal propagation in the forward direction and, in the case of bidirectional simulation, also in the reverse direction. For example, optical signal input pins defined for components of light signal propagation in the forward direction can include, but are not limited to: In[0] associated with the transverse electric (TE) mode and the real component, In[1] associated with the TE mode and the imaginary component, In[2] associated with the transverse magnetic (TM) mode and the real component, In[3] associated with the TM mode and the imaginary component, and In[4] associated with wavelength. Optical signal input pins defined for light signal propagation in the reverse direction can include, but are not limited to: In[5] associated with the TE mode and the real component, In[6] associated with the TE mode and the imaginary component, In[7] associated with the TM mode and the real component, In[8] associated with the TM mode and the imaginary component, and In[9] associated with wavelength. Similarly, optical signal output pins defined for components of light signal propagation in the forward direction can include, but are not limited to: Out[0] associated with the TE mode and the real component, Out[1] associated with the TE mode and the imaginary component, Out[2] associated with the TM mode and the real component, Out[3] associated with the TM mode and the imaginary component, and Out[4] associated with wavelength. Optical signal output pins defined for components of light signal propagation in the reverse direction can include, but are not limited to: Out[5] associated with the TE mode and the real component, Out[6] associated with the TE mode and the imaginary component, Out[7] associated with the TM mode and the real component, Out[8] associated with the TM mode and the imaginary component, and Out[9] associated with wavelength.

Additionally, the component descriptions of the photonic device cells in the cell library 311 can also define: (1) one or more physical parameter input pins for one or more physical parameters of note at each input terminal of a photonic device cell; and (2) one or more physical parameter output pins for the same physical parameter(s) of note at each output terminal of a photonic device cell. The physical parameter(s) of note can be any physical parameter where a mismatch in that physical parameter between optically coupled photonic devices can lead to optical signal transition loss. Such physical parameters include, but are not limited to, curvature radius, material composition, and physical dimensions (e.g., width or cross-sectional area). That is, the physical data input and output pins can include any of: In[10] PPin.curvrad and Out[10] PPout.curvrad associated with curvature radius; In[11] PPin.material and Out[11] PPout.material associated with material composition; In[12] PPin.wid and Out[12] PPout.wid associated with device width; etc. Thus, in these embodiments, each virtual bus between optically coupled photonic devices in a design layout will include pairs of optical signal input and output pins and at least one pair of physical data input and output pins.

For example, FIG. 4A is a drawing illustrating a portion of a design layout including a first photonic device 410, which has a light receiving terminal 411 (also referred to herein as an input terminal) optically coupled to a light emitting terminal 422 (also referred to herein as an output terminal) of a second photonic device 420 by a first virtual bus (bus 1), and which further has a light emitting terminal 412 optically coupled to a light receiving terminal 431 of a third photonic device 430 by a second virtual bus (bus 2). These first, second, and third photonic devices 410, 420, 430 can be any of waveguides, laser diodes, light-emitting diodes, optical couplers, optical splitters, optical amplifiers, photodetectors, bends, polarization beam splitter and rotators (PSRs), optical modulators, optical filters, etc. They can be the same type of photonic device (e.g., all waveguides, etc.) or different types of photonic devices. The component descriptions of cells in the cell library 311 for the first, second, and third photonic devices 410, 420, 430 can include defined optical signal input pins and physical data input pins for the light receiving terminals 411, 431 (e.g., see In[0-n]) and FIG. 4B) and defined optical signal output pins and physical data output pins for the light emitting terminals 422, 412 (e.g., see Out[0-n] and FIG. 4C).

Thus, referring again to the flow diagram of FIG. 2, in these embodiments a placement tool is executable by the processor at processes 202-204 to enable photonic device cell selection for inclusion in a design layout. As discussed above, in these embodiments, the design layout can include virtual buses between optically coupled photonic device and each virtual bus can include pairs of optical signal input and output pins associated with components of optical signal propagation and at least one pair of physical data pins for communication of physical parameter information. A netlist extraction tool is executable by the processor at process 206 to extract a netlist from the design layout. A simulation tool is executable by the processor at process 208 to perform the post-layout simulation(s) with coupling awareness to account for optical signal transition loss between optically coupled photonic devices. Specifically, during simulation, information communicated to the simulation tool via the pair(s) of physical data pins in each virtual bus can be employed to calculate physical parameter mismatch(es) between optically coupled photonic devices and to further calculate optical signal transition loss as a result of identified physical parameter mismatch(es). It should be noted that, in these embodiments, the extra signals added via the physical data input and output pins to communicate the physical parameter mismatch information doesn't require additional connecting from the designer because they are part of the same virtual bus. Furthermore, no additional utility is required in order to identify physical parameter mismatches.

Referring to FIGS. 5A-5D, in other embodiments, coupling awareness can be achieved through the use of custom coupling cell(s) as opposed to physical parameter pins. For example, FIG. 5A is a drawing illustrating a portion of a design layout including a first photonic device 510, which has a light receiving terminal 511 (also referred to herein as an input terminal) optically coupled to a light emitting terminal 522 (also referred to herein as an output terminal) of a second photonic device 520 by a first virtual bus (bus 1), and which further has a light emitting terminal 512 optically coupled to a light receiving terminal 531 of a third photonic device 530 by a second virtual bus (bus 2). The first, second, and third photonic devices 510, 520, 530 can include any of waveguides, laser diodes, light-emitting diodes, optical couplers, optical splitters, optical amplifiers, photodetectors, bends, polarization beam splitter and rotators (PSRs), optical modulators, optical filters, etc. They can be the same type or different types of photonic devices.

In these embodiments, the component descriptions (in CDF) of the photonic device cells in the cell library 311 can include optical signal input pins at each light receiving terminal (i.e., each input terminal) of a photonic device cell and optical signal output pins at each light emitting terminal (i.e., each output terminal)) of a photonic device cell, as discussed in the previous embodiment and illustrated in FIGS. 5B and 5C, respectively. However, physical data pins are not defined by the component descriptions for the photonic device cells. Thus, in these embodiments, in the initial design layout the first virtual bus (bus1) between the first photonic device 510 and the second photonic device 520 and the second virtual bus (bus2) between the first photonic device 510 and the third photonic device 530 will include pairs of optical signal input and output pins (e.g., In[0-9] and Out[0-9]) but no physical data pins, as indicated.

In the absence of such physical data pins, the mismatch utility 316 can be run on the initial design layout (e.g., of FIG. 5A) or on the schematic for the PIC. That is, the mismatch utility 316 can include program instructions, which are executable by a processor 350 to scan the initial design layout or schematic. This scan can be performed to identify any physical parameter mismatches of note (e.g., a curvature radius mismatch, a material composition mismatch, a physical dimension mismatch, etc.) in the design layout or schematic for the PIC. That is, it can be performed to identify the values of each physical parameter of note at the light receiving and light emitting terminals (i.e., the input and output terminals) of the photonic devices in the PIC, to determine which of the photonic devices are optically coupled, and to further identify and define the value of any physical parameter mismatch between any optically coupled photonic devices. The mismatch utility 316 can further include program instructions executable by the processor 350 to develop custom coupling cells for defining any physical parameter mismatches between any optically coupled photonic devices and for inserting the custom coupling cells into the design layout for the PIC between the optically coupled photonic devices. Each custom coupling cell between a pair of optically coupled photonic devices can have a component description (in a CDF) that indicates all the physical parameter mismatch information associated that pair of optically coupled photonic devices.

For example, referring to FIG. 5D, the mismatch utility 316 can determine that the first photonic device 510 is optically coupled to the second photonic device 520 (i.e., the light emitting terminal 522 of the second photonic device 520 is coupled to the light receiving terminal 511 of the first photonic device 510) and can further determine that the first photonic device 510 is also optically coupled to the third photonic device 530 (i.e., the light emitting terminal 512 of the first photonic device 510 is optically coupled to the light receiving terminal 531 of the third photonic device 530). The mismatch utility 316 can determine if there are any mismatches of any specific physical parameters of note (e.g., curvature radius, material composition, a physical dimension, etc.) between the first photonic device 510 and the second photonic device 520 and/or between the first photonic device 510 and the third photonic device 530. The mismatch utility can further develop, as needed, a first custom coupling cell 50a that defines the identified physical parameter mismatches (if any) between the first photonic device 510 and the second photonic device 520 and a second custom coupling cell 50b that defines the identified physical parameter mismatches (if any) between the first photonic device 510 and the third photonic device 530. The mismatch utility 316 can then insert (or cause to be inserted) the first custom coupling cell 50a and the second custom coupling cell 50b into the design layout between the first photonic device 510 and the second photonic device 520 and between the first photonic device 510 and the third photonic device 530, respectively. Subsequently, an updated netlist can be extracted from the design layout (which includes the custom coupling cells 50a-50b) and this updated netlist can be used for the simulation.

Thus, referring again to the flow diagram of FIG. 2, various EDA tools 320 including, but not limited to, placement and routing tools are executable by the processor at processes 202-204 to enable photonic device cell selection, placement, and routing to generate an initial design layout. As discussed above, in these embodiments, the design layout can include virtual buses between optically coupled photonic device and each virtual bus can include pairs of optical signal input and output pins associated with components of optical signal propagation but not physical data pins. Since the virtual buses do not include physical data pins, a mismatch utility is executable by the processor at process 205 to perform mismatch utility processing. As described above, such mismatch utility processing can include, but is not limited to, physical parameter mismatch identification and custom coupling cell development and design layout insertion. A netlist extraction tool is executable by the processor at process 206 to extract a netlist from the design layout, where the netlist includes virtual buses between each pair of optically coupled photonic devices and further includes custom coupling cell(s) inserted between each pair of optically coupled photonic devices with identified physical parameter mismatch(es) that could lead to optical signal transition loss. A simulation tool is executable by the processor at process 208 to perform the post-layout simulation(s) with coupling awareness. Specifically, during simulation, information communicated to the simulation tool via the custom coupling cell(s) can be employed to calculate optical signal transition loss based on identified physical parameter mismatch(es). It should be noted that, in these embodiments, while the extra mismatch utility adds complexity, implementation may be preferred in order to provide the designer with better understanding of connection between the optically coupled photonic devices. Furthermore, no additional utility is required in order to identify physical parameter mismatches.

Regardless of whether coupling awareness is achieved through the use of physical parameter pins or custom coupling cells, as described above, equations that could be employed by the optical signal propagation simulation program 315 to simulate optical signal propagation based on defined values for the TE mode and the real component, the TE mode and the imaginary component, the TM mode and the real component, the TM mode and the imaginary component, and wavelength are known in the art. Thus, these equations have been omitted from this specification in order to allow the reader to focus on simulation that further models and, thus, accounts for optical signal transition loss during optical signal propagation between optically coupled photonic devices. Additionally, it should be understood that when optical signal propagation is simulated between two optically coupled photonic devices having no physical parameter mismatches of note, then the following formula can be employed by the optical signal propagation simulation program 315 to calculate total optical signal loss:

$$Lt = L 1 + L 2 , \qquad ( 1 )$$

where Lt is the total optical signal loss and L1 and L2 are the optical signal losses exhibited by each photonic device individually. Techniques for calculating optical signal losses exhibited each photonic device individually are known in the art and, thus, the details thereof have been omitted from the specification to allow the reader to focus on the salient aspects of the disclosed embodiments. Additionally, it should be understood that when optical signal propagation is simulated between two optically coupled photonic devices having one or more physical parameter mismatches of note (e.g., a curvature radius mismatch, a material composition mismatch, a physical dimension mismatch, etc.), then the following formula for calculating the optical signal loss can be employed by the simulation tool at process 208:

$$Lt = L 1 + L 2 + Lts , \qquad ( 2 )$$

where Lts refers to the transition loss due to any physical parameter mismatch(es). Various formulas for calculating transition loss due to physical parameter mismatches (e.g., curvature radius mismatch, material composition mismatch, and/or dimension mismatch) are known in the art. Such formulas include, for example, formulas that calculate loss of a bend as a function of the radius of the bend. The optical signal propagation simulation program 315 can be configured to use (e.g., can include program instructions that use) physical parameter mismatch information as variables within such formulas to calculate Lts and, thereby Lt. As mentioned above, such physical parameter mismatch information can be communicated to the optical signal propagation program 315 via either physical parameter pins (e.g., as shown in FIGS. 4A-4C) or custom coupling cell(s) (e.g., as shown in FIGS. 5A-5D).

In the embodiments described above the types of simulation performed at process 208 of FIG. 2 can include optical signal propagation simulation, as described above, and optionally one or more other types of simulations including, but not limited to, direct current (DC) analysis, alternating current (AC) analysis, transient analysis, Monte Carlo analysis, or any other type of analysis (e.g., an S parameter and Fourier analysis, a noise analysis, etc.). Such simulation types are known in the art and, thus, the details thereof have been omitted from this specification in order to allow the reader to focus on the salient aspects of the disclosed embodiments. Optionally, the simulation model parameters used during simulation performed at process 208 can also include an on/off selection field for reverse optical signal propagation simulation and/or an on/off selection field for a swap function that switches the direction of signal propagation.

The disclosed embodiments allow predictions regarding performance (including limitations thereof) to be made prior to topological design of the PIC and, thus, avoid the need for design rules that prevent mismatches that lead to transition signal loss. The objective of optical coupling awareness is to identified physical parameter mismatches and determine the amount of performance loss resulting therefrom so that the designer can determine whether or not the resulting transition loss is tolerable and proceed accordingly (e.g., makes changes to the design and/or make some other trade-offs). Therefore, referring again to the flow diagram of FIG. 2 in combination with FIG. 3, following simulation at process 208, the simulation results 345 can be evaluated to determine whether or not performance specifications (e.g., requirements for optical signal propagation characteristics, such as power, amplitude, and/or signal phase, requirements for current-voltage (I-V) characteristics, etc.) for the PIC have been met or not (see process 210). Evaluation of the simulation results 345 can be performed manually by the user based on the output, automatically by the processor, and/or by a combination of both automatic and manual evaluation processes. In any case, if one or more of the performance specifications have not been met, processes 204-210 can be iteratively repeated adjusting the design layout 341 or making other trade-offs until such performance specifications have been met.

Once the performance specifications have been met, a final PIC design layout 343 can be stored and released to tape-out (e.g., in a binary database file format suitable for EDA data exchange on PIC layout artwork, such as in a graphic design system (GDS) format or GDS II format) (see process 212). Those skilled in the art will recognize that one or more other verification processes (e.g., timing and signal integrity verification, physical verification, electromigration fails and voltage drop verification, etc.) may, optionally, be performed before completing the final IC design layout. Once the final IC design layout 343 is completed, it can be released to manufacturing so that PIC chips can be manufactured accordingly.

Embodiments disclosed herein may be implemented as a system, a method, a computer program product and/or a PDK product. A computer program product may include a computer readable storage medium (or media) having, embodied therewith, any of the above-described PIC design programs including, but not limited to, the optical signal propagation simulation program and, particularly, program instructions thereof for causing a processor to carry out aspects of the disclosed embodiments. A PDK product may similarly include a computer readable storage medium (or media) having, embodied therewith, any of the above-described PIC design programs including, but not limited to, the optical signal propagation simulation program and, particularly, program instructions thereof for causing a processor to carry out aspects of the disclosed embodiments. As discussed in greater detail above, the computer readable storage medium (or media) of a PDK product can further have embodied therewith design data files (e.g., symbols and technology files for the specific technology node, design rule decks for various stages in the design process, etc.) that can be employed by EDA tools during PIC design to facilitate the PIC design process.

In any case, a computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the disclosed embodiments may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the disclosed embodiments.

Aspects of the disclosed embodiments are described herein with reference to flowchart illustrations and/or block diagrams of methods, apparatus (systems), and computer program products according to disclosed embodiments. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various disclosed embodiments. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

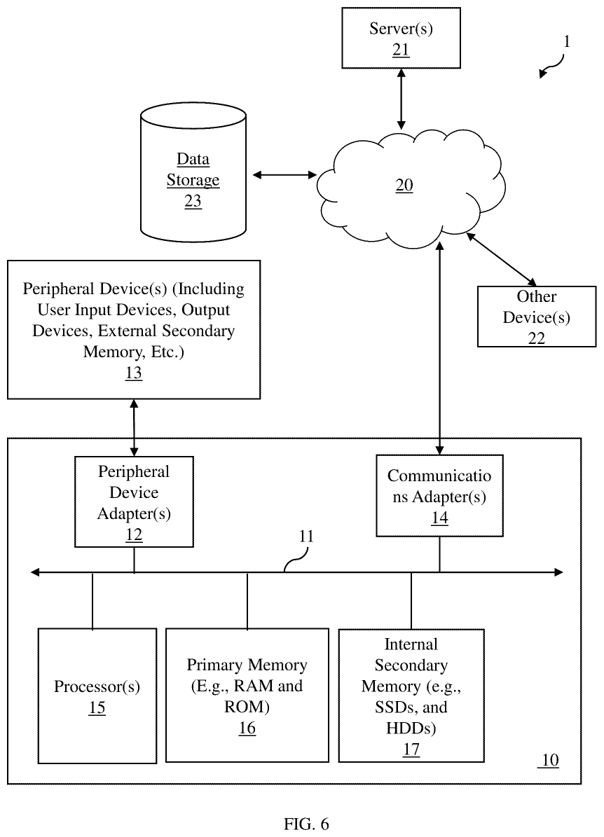

An illustrative hardware environment 1 for implementing aspects of the disclosed systems, methods and computer program products is depicted in FIG. 6. Generally, the hardware environment can include at least one computing device 10 (also referred to herein as a computer). Computer 10 can be, for example, a desktop, laptop, tablet, mobile computing device, etc. Computer 10 can include at least one bus 11. Bus 11 can be connected to various other components of the computer 10 and can be configured to facilitate communication between those components.

The computer 10 can include various adapters. The adapters can include one or more peripheral device adapters 12, which are configured to facilitate communications between one or more peripheral devices 13, respectively, and the bus 11. Peripheral devices 13 can include user input devices configured to receive user inputs. User input devices can include, but are not limited to, a keyboard, a mouse, a microphone, a touchpad, a touchscreen, a stylus, biosensor, a scanner, or any other type of user input device. Peripheral devices 13 can also include additional input devices, such as external secondary memory devices (as discussed in greater detail below). The peripheral devices 13 can also include output devices. The output devices can include, but are not limited to, a printer, a monitor, a speaker, or any other type of computer output device. The adapters can include one or more communications adapters 14 (also referred to herein as a computer network adapters), which are configured to facilitate communications between the computer 10 and one or more communications networks 20 (e.g., a wide area network (WAN), a local area network (LAN), the internet, a cellular network, a Wi-Fi network, etc.). Such network(s) 20 can, in turn, facilitate communications between the computer 10 and other system components on the network: remote server(s) 21, other device(s) 22 (e.g., computers, laptops, tablets, mobile phones, etc.), remote data storage 23, etc.

The computer 10 can further include at least one processor 15 (also referred to herein as a central processing unit (CPU)). Optionally, each CPU 15 can include a CPU cache. Each CPU 15 can be configured to read and execute program instructions.

The computer 10 can further include memory and, particularly, computer-readable storage mediums. The memory can include primary memory 16 and secondary memory. The primary memory 16 can include, but is not limited to, random access memory (RAM) (e.g., volatile memory employed during execution of program operations) and read only memory (ROM) (e.g., non-volatile memory employed during start-up). The RAM can include, but is not limited to, dynamic random access memory (DRAM), static random access memory (SRAM), or any other suitable type of RAM. The ROM can include, but is not limited to, erasable programmable read only memory (EPROM), flash memory, electronically erasable programmable read only memory (EEPROM), programmable read only memory (PROM), or any other suitable type of ROM. The secondary memory can be non-volatile. The secondary memory can include internal secondary memory 17, such as internal solid state drive(s) (SSD(s)) and/or internal hard disk drive(s) (HDD(s), installed within the computer 10 and connected to the bus 11. The secondary memory can also include external secondary memory connected to or otherwise in communication with the computer 10 (e.g., peripheral devices). The external secondary memory can include, for example, external/portable SSD(s), external/portable HDD(s), flash drive(s), thumb drives, compact disc(s) (CD(s)), digital video disc(s) (DVD(s)), network-attached storage (NAS), storage area network (SAN), or any other suitable non-transitory computer-readable storage media connected to or otherwise in communication with the computer 10. The different functions of primary and secondary memory are well known in the art and, thus, the details thereof have been omitted from this specification in order to allow the reader to focus on the salient aspects of the disclosed embodiments.

In some embodiments, program instructions for performing the disclosed method or a portion thereof, as described above, can be embodied in (e.g., stored in) secondary memory accessible by computer 10. When the program instructions are to be executed (e.g., in response to user inputs to the computer 10), required information (e.g., the program instructions and other data) can be loaded into the primary memory (e.g., stored in RAM). The CPU 15 can read the program instructions and other data from the RAM and can execute the program instructions. In other embodiments, a client-server model can be employed. In this case, the computer 10 can be a client and a remote server 21 in communication with the computer 10 over a network 20 can provide, to the client, a service including execution of program instructions for performing the disclosed method or a portion thereof, as described above, in response to user inputs the computer 10.

It should be understood that the terminology used herein is for the purpose of describing the disclosed structures and methods and is not intended to be limiting. For example, as used herein, the singular forms “a,” “an,” and “the” are intended to include the plural forms as well, unless the context clearly indicates otherwise. Additionally, as used herein, the terms “comprises,” “comprising,” “includes,” and/or “including” specify the presence of stated features, integers, steps, operations, elements, and/or components, but do not preclude the presence or addition of one or more other features, integers, steps, operations, elements, components, and/or groups thereof. Furthermore, as used herein, terms such as “right,” “left,” “vertical,” “horizontal,” “top,” “bottom,” “upper,” “lower,” “under,” “below,” “underlying,” “over,” “overlying,” “parallel,” “perpendicular,” etc., are intended to describe relative locations as they are oriented and illustrated in the drawings (unless otherwise indicated) and terms such as “touching,” “in direct contact,” “abutting,” “directly adjacent to,” “immediately adjacent to,” etc., are intended to indicate that at least one element physically contacts another element (without other elements separating the described elements). The term “laterally” is used herein to describe the relative locations of elements and, more particularly, to indicate that an element is positioned to the side of another element as opposed to above or below the other element, as those elements are oriented and illustrated in the drawings. For example, an element that is positioned laterally adjacent to another element will be beside the other element, an element that is positioned laterally immediately adjacent to another element will be directly beside the other element, and an element that laterally surrounds another element will be adjacent to and border the outer sidewalls of the other element. The corresponding structures, materials, acts, and equivalents of all means or step plus function elements in the claims below are intended to include any structure, material, or act for performing the function in combination with other claimed elements as specifically claimed.

The descriptions of the various disclosed embodiments have been presented for purposes of illustration but are not intended to be exhaustive or limiting. Many modifications and variations will be apparent to those of ordinary skill in the art without departing from the scope and spirit of the disclosed embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A system including:
a storage medium storing a netlist for a photonic integrated circuit; and
a processor in communication with the storage medium, wherein the processor performs a signal propagation simulation using the netlist, and wherein the signal propagation simulation accounts for signal loss due to a difference between a specific physical parameter of a first photonic device and the specific physical parameter of a second photonic device receiving an optical signal from the first photonic device.

2. The system of claim 1, wherein the specific physical parameter is any of a curvature radius, a material composition, and a physical dimension.

3. The system of claim 1, wherein the processor further enables iterative design processing until simulation results indicate that performance specifications are met and, when the performance specifications are met, generates and outputs a final design layout for manufacture.

4. The system of claim 1,
wherein the netlist includes a bus between the first photonic device and the second photonic device,
wherein the bus includes at least one pair of physical data pins representing the specific physical parameter of the first photonic device and the specific physical parameter of the second photonic device, and
wherein the signal propagation simulation is performed using information communicated through the pair of physical data pins.

5. The system of claim 4,
wherein the storage medium further stores a process design kit including a library of cells, placement and routing tools, a netlist extraction tool, and a simulation tool,
wherein the library of cells includes photonic device cells and each photonic device cell includes a component description defining pins at each terminal that any of emits light signals and receives light signals,
wherein the pins are associated with components of signal propagation and with at least one physical parameter,
wherein the placement and routing tools are executable by the processor to enable photonic device cell selection, placement, and routing in a design layout,
wherein the netlist extraction tool is executable by the processor to extract the netlist from the design layout, and
wherein the simulation tool is executable by the processor to perform the signal propagation simulation.

6. The system of claim 1,
wherein the storage medium further stores a mismatch utility,
wherein the processor executes the mismatch utility to scan one of a design layout for the photonic integrated circuit and a schematic diagram for the photonic integrated circuit to identify the difference in the specific physical parameter of the first photonic device and the specific physical parameter of the second photonic device, and
wherein, based on the difference in the specific physical parameter of the first photonic device and the specific physical parameter of the second photonic device, the processor inserts a custom coupling cell, including physical parameter mismatch information, into the design layout between the first photonic device and the second photonic device and further extracts the netlist from the design layout with the custom coupling cell.

7. The system of claim 6,
wherein the storage medium further stores a process design kit including a library of cells, placement and routing tools, a netlist extraction tool, and a simulation tool,
wherein the library of cells includes photonic device cells and each photonic device cell includes a component description defining pins at each terminal that any of emits light signals and receives light signals,
wherein the placement and routing tools are executable by the processor to enable photonic device cell selection, placement and routing in a design layout,
wherein the mismatch utility is executable by the processor to scan the design layout to identify the difference in the specific physical parameter of the first photonic device and the specific physical parameter of the second photonic device, to develop the custom coupling cell with the physical parameter mismatch information, and to insert the custom coupling cell into the design layout,
wherein the netlist extraction tool is executable by the processor to extract the netlist from the design layout that includes the custom coupling cell, and
wherein the simulation tool is executable by the processor to perform the signal propagation simulation.

8. The system of claim 1, wherein the signal propagation simulation includes forward and reverse signal propagation simulation.

9. The system of claim 1, wherein the signal propagation simulation further accounts for additional signal losses due to a difference between at least one additional physical parameter of the first photonic device and the second photonic device.

10. A method including:
accessing, by a processor from a storage medium, a netlist for a photonic integrated circuit; and
performing, by the processor, a signal propagation simulation using the netlist, wherein the signal propagation simulation accounts for signal loss due to a difference in a specific physical parameter of a first photonic device and the specific physical parameter of a second photonic device receiving an optical signal from the first photonic device.

11. The method of claim 10, wherein the specific physical parameter is any of a curvature radius, a material composition, and a physical dimension.

12. The method of claim 10, further comprising:
evaluating results of the optical signal propagation simulation to determine whether performance specifications have been met;
performing iterative design processing until the results indicate that the performance specifications have been met;
when the performance specifications have been met, generating and outputting a final design layout; and
manufacturing the photonic integrated circuit based on the final design layout.

13. The method of claim 10,
wherein the netlist includes a bus between the first photonic device and the second photonic device,
wherein the bus includes at least one pair of physical data pins representing the specific physical parameter of the first photonic device and the specific physical parameter of the second photonic device, and
wherein the signal propagation simulation is performed using information communicated through the pair of physical data pins.

14. The method of claim 10, further comprising, before the performing of the simulation, scanning, by the processor, one of a design layout for the photonic integrated circuit and a schematic diagram for the photonic integrated circuit to identify the difference in the specific physical parameter of the first photonic device and the specific physical parameter of the second photonic device;
based on the difference in the specific physical parameter of the first photonic device and the specific physical parameter of the second photonic device, inserting, by the processor, a custom coupling cell, including physical parameter mismatch information, into the design layout between the first photonic device and the second photonic device; and
extracting, by the processor, the netlist from the design layout that includes the custom coupling cell.

15. The method of claim 10, wherein the signal propagation simulation includes forward and reverse signal propagation simulation.

16. The method of claim 10, wherein the signal propagation simulation further accounts for additional signal losses due to a difference in at least one additional physical parameter between the first photonic device and the second photonic device.

17. A product comprising a computer readable storage medium having program instructions embodied therewith, the program instructions being executable by a processor to cause the processor to perform a method including:
accessing a netlist for a photonic integrated circuit; and
performing a signal propagation simulation using the netlist, wherein the signal propagation simulation accounts for signal loss due to a difference in a specific physical parameter of a first photonic device and the specific physical parameter of a second photonic device receiving an optical signal from the first photonic device.

18. The product of claim 17, wherein the specific physical parameter is any of a curvature radius, a material composition, and a physical dimension.

19. The product of claim 17, wherein the signal propagation simulation includes forward and reverse signal propagation simulation.

20. The product of claim 17, wherein the signal propagation simulation further accounts for additional signal loss due to a difference in at least one additional physical parameter between the first photonic device and the second photonic device.
